(19) United States
(12) Patent Application Publication
(10) Pub. No.: US 2025/0124658 A1
(43) Pub. Date: Apr. 17, 2025

(54) SYSTEMS AND METHODS FOR CROSS-SECTIONING OF CIRCUIT BOARDS

(71) Applicant: Dell Products L.P., Round Rock, TX (US)

(72) Inventors: Sandor T. FARKAS, Round Rock, TX (US); Steven R. ETHRIDGE, Austin, TX (US); Bhyrav M. MUTNURY, Austin, TX (US)

(73) Assignee: Dell Products L.P., Round Rock, TX (US)

(21) Appl. No.: 18/485,067

(22) Filed: Oct. 11, 2023

(51) Int. Cl. G06T 19/00; B26D 7/27; H05K 3/22

(52) U.S. Cl. CPC G06T 19/00; B26D 7/27; H05K 3/22; H05K 2203/162

(57) ABSTRACT

A method may include slicing a circuit board at multiple parallel cross-sections of the circuit board, each slice of the circuit board taken in a respective slice plane substantially non-perpendicular and substantially non-parallel to a surface of the circuit board.

### TECHNICAL FIELD

The present disclosure relates in general to information handling systems, and more particularly to cross-sectioning of circuit boards, which may be used in information handling systems, during testing and evaluation of such circuit boards.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often use one or more circuit boards. A circuit board may comprise a substrate of a plurality of conductive layers separated and supported by layers of dielectric insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

Circuit boards are manufactured with tolerances, including layer-to-layer shift, drilling tolerances for primary drilling and back drilling of via stubs, laminate thickness variations, and other tolerances. Accordingly, there is often a desire to audit the fabrication process for circuit boards to check tolerances.

Cross-sectioning of a circuit board, for example with cutting tools, may be an economical way to check manufacturing tolerances. However, most board features are parallel or perpendicular to the board surface, and the perpendicular to surface cross-sectional slices used in traditional approaches often miss manufacturing problems. To illustrate, FIGS. 1A-1D illustrate various steps in creating a back drilled and filled via in a circuit board, as is known in the art. FIG. 1A depicts a via 10 as designed, including coupling to pads 12. FIG. 1B depicts via 10 as manufactured with tolerances between metal layers 14 included and unused pads 16 removed. FIG. 1C depicts via 10 after back drilling, and FIG. 1D depicts the addition of fill 18. FIGS. 1C and 1D show presence of voids 20 in fill 18, poor registration of metal layers 14, and poor registration of back drilling, leaving behind an undesired via stripe 22.

FIG. 2 illustrates a cross section of a circuit board with a slice made perpendicular to a surface of a circuit board, as is known in the art. As suggested by FIG. 2, because stripes 22 are often parallel to the slices made in cross-sectioning a circuit board, and because stripes can be as thin as 0.1 mil while slices are 2 mils thick, stripes 22 can be missed. Voids 20 may also be missed in traditional approaches.

Accordingly, improved methods and systems for detecting problems due to manufacturing tolerances in circuit boards are desired.

### SUMMARY

In accordance with the teachings of the present disclosure, the disadvantages and problems associated with existing approaches to mounting a circuit package to a printed circuit board may be reduced or eliminated.

In accordance with embodiments of the present disclosure, a method may include slicing a circuit board at multiple parallel cross-sections of the circuit board, each slice of the circuit board taken in a respective slice plane substantially non-perpendicular and substantially non-parallel to a surface of the circuit board.

In accordance with these and other embodiments of the present disclosure, a method may include imaging a plurality of cross-sectional slices of a circuit board, each cross-sectional slice of the circuit board taken in a respective slice plane substantially non-perpendicular and substantially non-parallel to a surface of the circuit board, in order to generate a respective image for each cross-sectional slice.

In accordance with these and other embodiments of the present disclosure, an article of manufacture may include a non-transitory computer-readable medium and computer-executable instructions carried on the computer-readable medium, the instructions readable by a processor, the instructions, when read and executed, for causing the processor to image a plurality of cross-sectional slices of a circuit board, each cross-sectional slice of the circuit board taken in a respective slice plane substantially non-perpendicular and substantially non-parallel to a surface of the circuit board, in order to generate a respective image for each cross-sectional slice.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIGS. 1A-1D illustrate various steps in creating a back drilled and filled via in a circuit board, as is known in the art;

FIG. 2 illustrates a cross section of a circuit board with a slice made perpendicular to a surface of a circuit board, as is known in the art;

FIGS. 3A-3H illustrate various selected cross sections of a circuit board with slices made substantially non-perpendicular and substantially non-parallel to a surface of a circuit board, in accordance with embodiments of the present disclosure; and

FIG. 4 illustrates results of overlaying of images of multiple substantially non-perpendicular and non-parallel cross-sectional slices of a circuit board with data interpolation between successive slices to generate a three-dimensional image of a portion of the circuit board, in accordance with embodiments of the present disclosure.

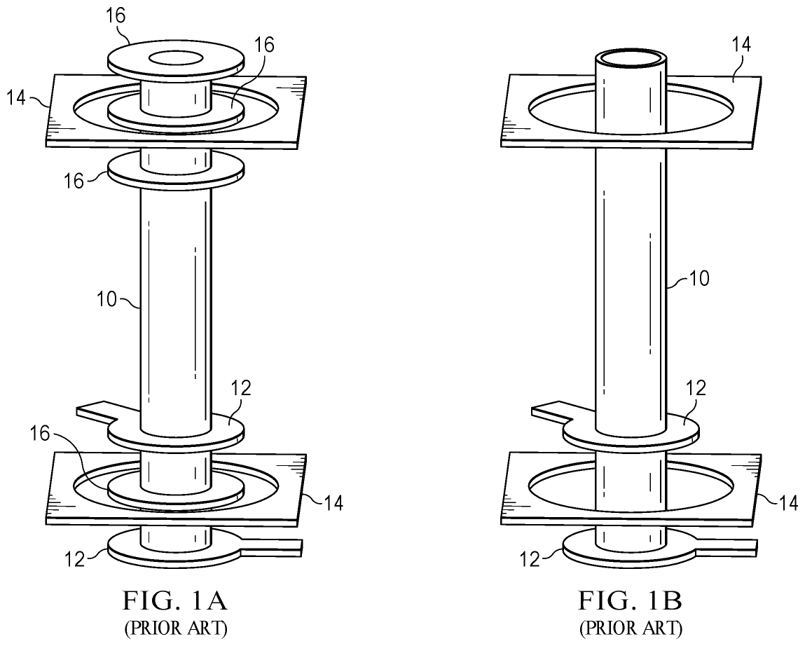

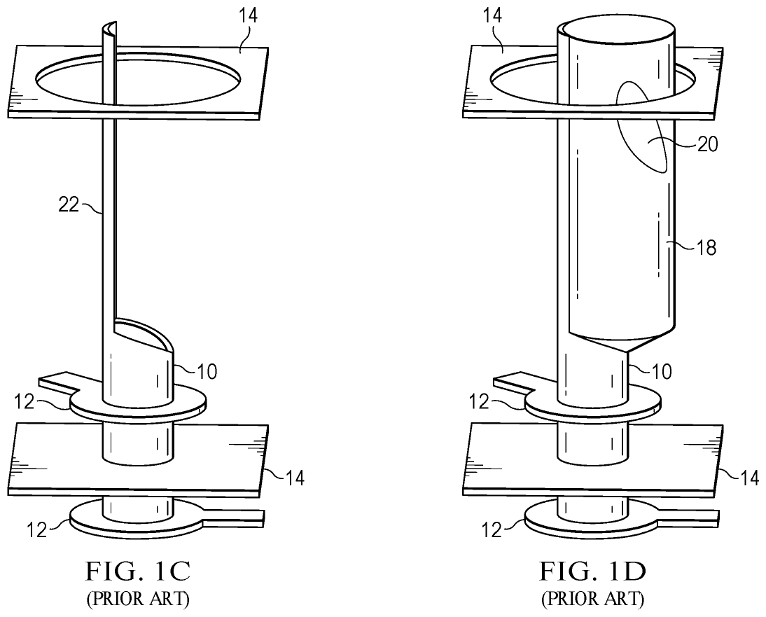

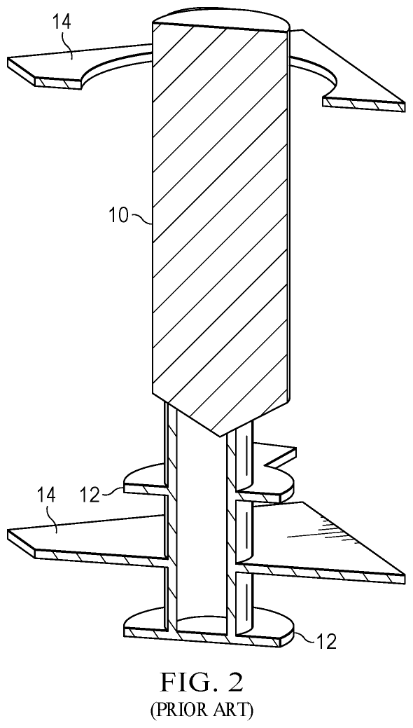

### DETAILED DESCRIPTION

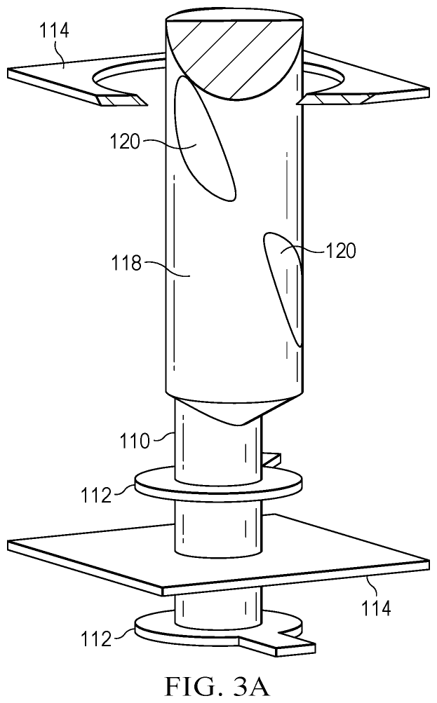

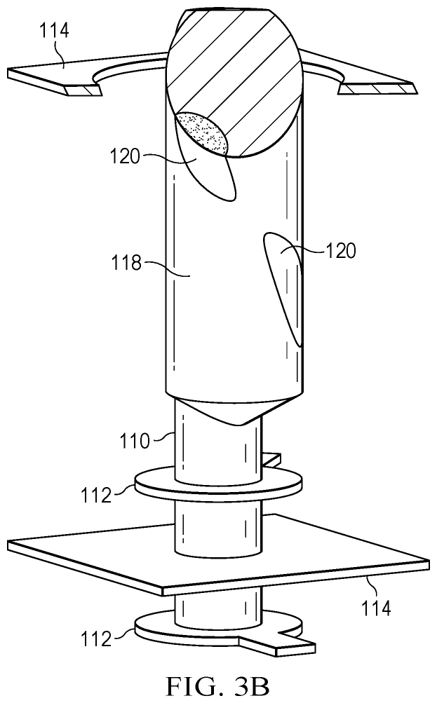

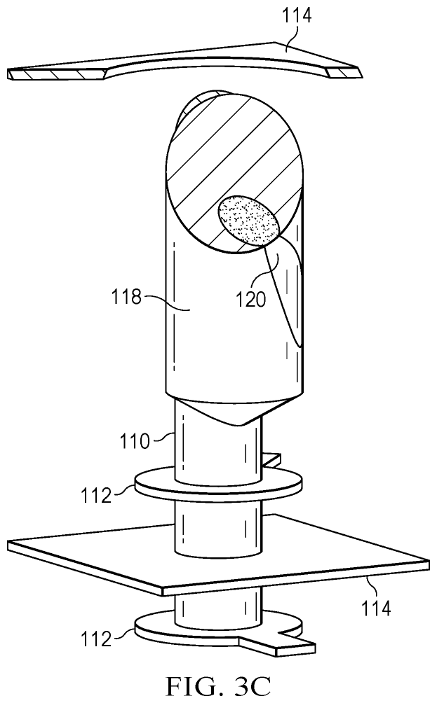

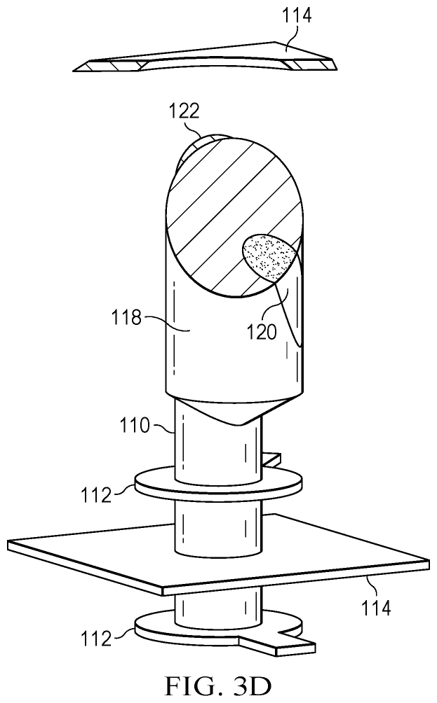

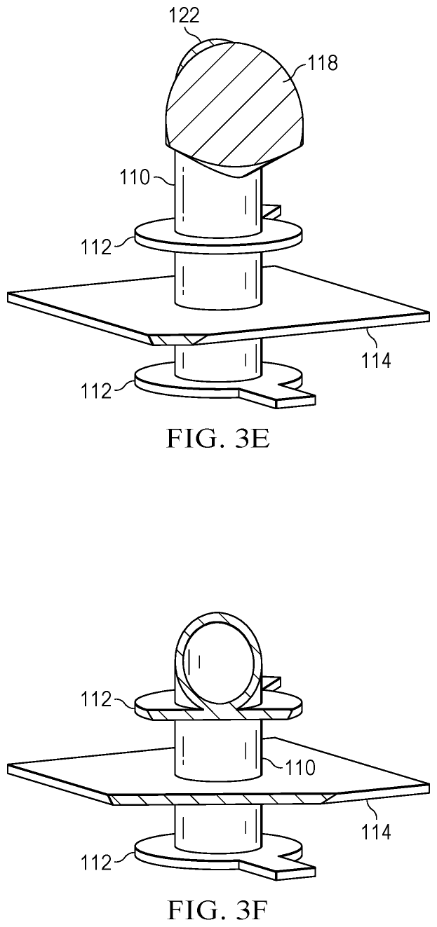

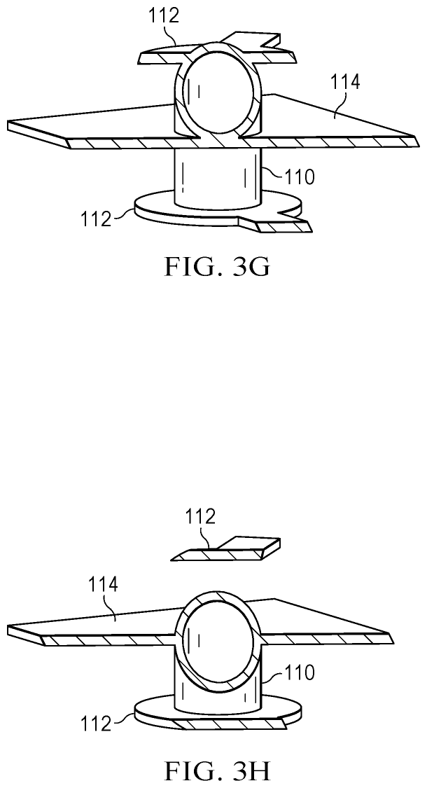

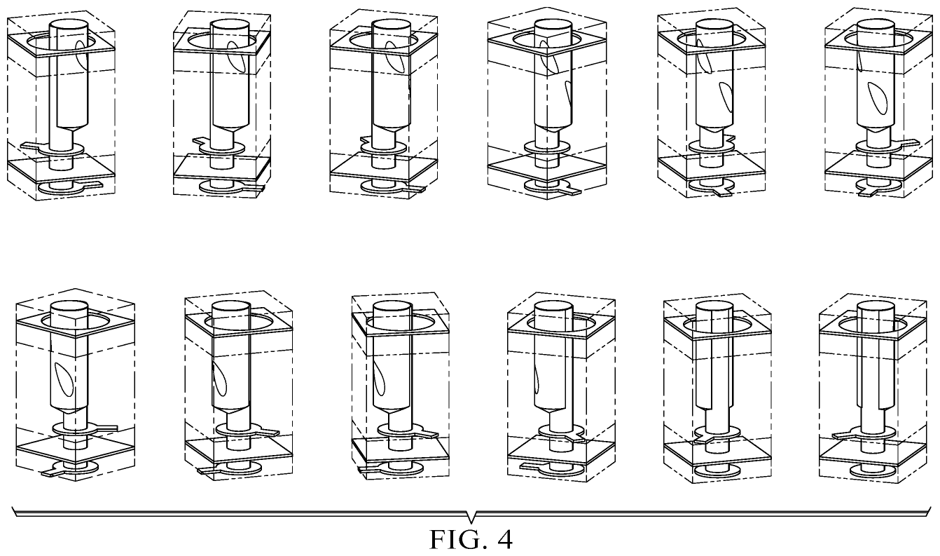

Preferred embodiments and their advantages are best understood by reference to FIGS. 3A-3H and 4 wherein like numbers are used to indicate like and corresponding parts. For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or r hardware or software control logic. Additional components of the information handling system may include one or more storage one devices, or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIGS. 3A-3H illustrate various selected cross sections of selected layers of a circuit board with slices made substantially non-perpendicular and substantially non-parallel to a surface of a circuit board, in accordance with embodiments of the present disclosure. For purposes of clarity and exposition, dielectric material between metal layers 114 of circuit board is omitted, while a via 110 and pads 112 coupled to via 110 are shown.

As shown in FIGS. 3A-3H, cross-sectional slices may be made with the same tools used for traditional approaches, but may be made along a plane that is substantially non-perpendicular and substantially non-parallel to the surface of the circuit board, for example at an angle that is at 45 degrees relative to the surface of the circuit board. Further, if the surface of the circuit board is thought of as being a plane having an x-axis and a y-axis, with a z-axis perpendicular to such plane, the plane of the cross-sectional slices may be tilted 45 degrees (or any other suitable non-parallel and non-perpendicular angle) relative to the x-axis and rotated 45 degrees (or any other suitable non-parallel and non-perpendicular angle) relative to the y-axis.

As shown in FIGS. 3A-3H, by taking cross sections in such manner, such approach may enable slices through a via stripe 122 and voids 120 formed within fill 118 on multiple cross sections, which may enable not only detection of the presence of voids 120 and stripe 122, but may also enable detection of sizes and shapes of such voids 120 and stripe 122.

Another advantage to the angled cross-sectional slice approach disclosed herein is that not only may such approach provide more information per cross-sectional slice than traditional approaches, but may also allow for more cross-sectional slices to be made on a circuit board as compared to traditional approaches.

Accordingly, using the angled cross-sectional slice approach disclosed herein, images of such cross-sections may be used, with data interpolation between successive slices, to generate a three-dimensional image of a circuit board. For example, FIG. 4 illustrates results of overlaying of images of multiple substantially non-perpendicular and non-parallel cross-sectional slices of a circuit board (e.g., as shown in FIGS. 3A-3H and described above) with data interpolation between successive slices to generate a three-dimensional image of a selected portion of the circuit board, in accordance with embodiments of the present disclosure.

Accordingly, a program of computer-executable instructions, embodied in non-transitory computer-readable media, may be configured to capture the images of each cross-sectional slice and to transform the tilted and rotated images to Cartesian coordinates to overlay the images in one three-dimensional space, interpolate (e.g., with a three-dimensional low-pass filter) between the slices to fill in missing three-dimensional pixels, display the three-dimensional image (e.g., with transparent colors for solid materials), and provide software controls for rotating, tilting, and/or measuring details.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A method comprising:
slicing a circuit board at multiple parallel cross-sections of the circuit board, each slice of the circuit board taken in a respective slice plane substantially non-perpendicular and substantially non-parallel to a surface of the circuit board.

2. The method of claim 1, wherein the respective slice planes are each approximately 45 degrees relative to the surface.

3. The method of claim 1, wherein with the surface of the circuit board defining a reference plane having a first axis and a second axis perpendicular to the first axis, each respective slice plane is tilted a substantially non-perpendicular and substantially non-parallel first angle from the first axis and rotated a substantially non-perpendicular and substantially non-parallel second angle from the second axis.

4. The method of claim 3, wherein at least one of the first axis and one of the second axis is approximately 45 degrees.

5. The method of claim 1, further comprising imaging each cross-sectional slice of the circuit board to generate a respective image for each cross-sectional slice.

6. The method of claim 5, further comprising overlaying the respective images to create a three-dimensional image of the circuit board.

7. The method of claim 6, further comprising data interpolating between the respective images to create the three-dimensional image.

8. A method comprising:
imaging a plurality of cross-sectional slices of a circuit board, each cross-sectional slice of the circuit board taken in a respective slice plane substantially non-perpendicular and substantially non-parallel to a surface of the circuit board, in order to generate a respective image for each cross-sectional slice.

9. The method of claim 8, wherein the respective slice planes are each approximately 45 degrees relative to the surface.

10. The method of claim 8, wherein with the surface of the circuit board defining a reference plane having a first axis and a second axis perpendicular to the first axis, each respective slice plane is tilted a substantially non-perpendicular and substantially non-parallel first angle from the first axis and rotated a substantially non-perpendicular and substantially non-parallel second angle from the second axis.

11. The method of claim 10, wherein at least one of the first axis and one of the second axis is approximately degrees.

12. The method of claim 8, further comprising overlaying the respective images to create a three-dimensional image of the circuit board.

13. The method of claim 12, further comprising data interpolating between the respective images to create the three-dimensional image.

14. An article of manufacture comprising:
a non-transitory computer-readable medium; and
computer-executable instructions carried on the computer-readable medium, the instructions readable by a processor, the instructions, when read and executed, for causing the processor to:
image a plurality of cross-sectional slices of a circuit board, each cross-sectional slice of the circuit board taken in a respective slice plane substantially non-perpendicular and substantially non-parallel to a surface of the circuit board, in order to to generate a respective image for each cross-sectional slice.

15. The article of claim 14, wherein the respective slice planes are each approximately 45 degrees relative to the surface.

16. The article of claim 14, wherein with the surface of the circuit board defining a reference plane having a first axis and a second axis perpendicular to the first axis, each respective slice plane is tilted a substantially non-perpendicular and substantially non-parallel first angle from the first axis and rotated a substantially non-perpendicular and substantially non-parallel second angle from the second axis.

17. The article of claim 16, wherein at least one of the first axis and one of the second axis is approximately degrees.

18. The article of claim 14, further comprising overlaying the respective images to create a three-dimensional image of the circuit board.

19. The article of claim 18, further comprising data interpolating between the respective images to create the three-dimensional image.
